(19) United States
(12) Patent Application Publication
(10) Pub. No.: US 2026/0128757 A1
(43) Pub. Date: May 7, 2026

(54) MILLIMETER-WAVE LOW-PASS OR HIGH-PASS RECONFIGURABLE FILTER

(71) Applicant: HANGZHOU DIANZI UNIVERSITY, Hangzhou (CN)

(72) Inventors: Jincai WEN, Hangzhou (CN); Xu WANG, Hangzhou (CN)

(21) Appl. No.: 19/434,303

(22) Filed: Dec. 29, 2025

Related U.S. Application Data
(63) Continuation of application No. PCT/CN2023/108121, filed on Jul. 19, 2023.

(30) Foreign Application Priority Data
Jun. 30, 2023 (CN) 202310803032.4

(51) Int. Cl. H04B 1/40; H03H 1/00; H03H 9/46; H04B 1/00

(52) U.S. Cl. CPC H04B 1/40; H03H 1/0007; H03H 9/46; H04B 1/006

(57) ABSTRACT

A millimeter-wave low-pass/high-pass reconfigurable filter comprising a series-parallel reconfiguration structure, a passband compensation inductor, and a ground-direct connection reconfiguration structure is disclosed. It enables the interchange of filter passband and stopband in two modes, achieving reconfigurable output in both high-frequency and low-frequency bands, along with low loss in the passband and effective image signal rejection in the stopband, thereby realizing hardware reuse. The circuit structure of the millimeter-wave low-pass/high-pass reconfigurable filter according to the invention is compact and well-suited for use in multi-band millimeter-wave reconfigurable transceivers.

### CROSS-REFERENCE TO RELATED APPLICATIONS

This application is a continuation of International Patent Application No. PCT/CN2023/108121 with a filing date of Jul. 19, 2023, designating the United States, now pending, and further claims priority to Chinese Patent Application No. 202310803032.4 with a filing date of Jun. 30, 2023. The content of the aforementioned applications, including any intervening amendments thereto, are incorporated herein by reference.

### TECHNICAL FIELD

The disclosure relates to a millimeter-wave low-pass/high-pass reconfigurable filter circuit for signal filtering in different frequency bands through reconfigurable technologies. It is used in microwave and millimeter-wave integrated circuits and belongs to the technical field of filters.

### BACKGROUND ART

The millimeter-wave frequency band, with its advantages of high frequency, wide bandwidth, and abundant spectrum resources, has become a research hotspot for realizing compact, high-speed, and high-capacity wireless communication systems. It holds promising application prospects in many fields such as communications and radar. Meanwhile, as the spectrum resources in low-GHz frequency bands have been extensively utilized and are gradually depleting, the millimeter-wave frequency band has become the preferred choice for high-speed wireless data transmission. Currently, the spectrum for the fifth-generation mobile communication technology (5G) has been classified as two frequency bands, one is the FR1 band (450 MHz-7 GHz), which is a low-frequency band centered around 3.5 GHz, characterized by long transmission distances and strong signal penetration, making it the primary band for 5G; the other is the FR2 millimeter-wave band (24.25˜71 GHz), which features high transmission rates and abundant spectrum resources. Among these, the 2019 World Radiocommunication Conference (WRC) designated 24.25˜29.5 GHz and 37˜43.5 GHz as the two mainstream millimeter-wave bands for 5G. Furthermore, to achieve higher communication capacity, millimeter-wave communication can also utilize multiple frequency bands to expand the communication bandwidth further.

Millimeter-wave filters, including low-pass filters, high-pass filters, and band-pass filters, are one of the key modules in millimeter-wave transceiver front-ends. Currently, various millimeter-wave filters operating at different fixed frequency bands have been realized. However, millimeter-wave filters capable of simultaneously performing frequency selection for signals in different bands are very few, and no millimeter-wave filter has been found that can switch between passband and stopband states to filter multiple different frequency bands while possessing stop band suppression characteristics. When future millimeter-wave communication systems operate across multiple frequency bands to achieve greater communication capacity and more flexible networking, if the method of switching between multiple fixed-band millimeter-wave filter circuits is still employed, it would make the communication system very complex and lead to increased cost, power consumption, and size, making it difficult to meet the needs of multi-band wireless communication systems, especially mobile devices. Therefore, developing millimeter-wave filter structures that can operate at different frequency bands will enable hardware circuit reuse, simplify the architecture of communication systems, and simultaneously reduce cost and power consumption.

### SUMMARY

To overcome the deficiencies in the existing research, the disclosure provides a millimeter-wave low-pass/high-pass reconfigurable filter that achieves the interchange of filter passband and stopband in two modes, realizes reconfigurable filtering output across multiple frequency bands, and exhibits low passband loss as well as good image signal suppression in the stopband.

A millimeter-wave low-pass/high-pass reconfigurable filter is disclosed, which includes a series-parallel reconfiguration structure, a passband compensation inductor, and a ground-direct connection reconfiguration structure.

The series-parallel reconfiguration structure is a parallel resonant network including a first switch, a second switch, a third switch, a first inductor and first capacitor. An input terminal is connected to one end of the first switch and one end of the second switch. The other end of the first switch is connected to one end of the first capacitor and one end of the first inductor. The other end of the second switch is connected to the other end of the first capacitor and one end of the third switch. The other end of the third switch is connected to the other end of the first inductor. The aforementioned components together constitute the series-parallel reconfiguration structure.

The passband compensation inductor includes a second inductor. One end of the second inductor is connected to the other end of the third switch and the other end of the first inductor. The other end of the second inductor is connected to one end of a fourth switch and one end of a fifth switch. The passband compensation inductor is configured to resonate out the passband capacitance of the series-parallel reconfiguration structure.

The ground-direct connection reconfiguration structure is a series resonant network including a fourth switch, a fifth switch, a sixth switch, a third inductor and second capacitor. The other end of the fourth switch is connected to one end of the second capacitor and one end of the sixth switch. The other end of the sixth switch is grounded. The other end of the fifth switch is connected to one end of the third inductor and an output terminal. The other end of the third inductor is connected to the other end of the second capacitor. The aforementioned components together constitute the ground-direct connection reconfiguration structure.

Preferably, the first switch, the third switch, the fifth switch, and the sixth switch are switched using the same control signal, meaning they are turned on and off simultaneously. The second switch and the fourth switch are switched using the same control signal, meaning they are turned on and off simultaneously.

Preferably, the first switch, the second switch, the third switch, the fourth switch, the fifth switch, and the sixth switch are all NMOS transistor switches, wherein their gates serve as switch control terminals, and their sources and drains serve as the two terminals of the switch respectively. When the first, second, third, fourth, fifth, and sixth switches are turned on, the NMOS transistor switches are equivalent to resistors; when turned off, they are equivalent to capacitors. Reconfigurable frequency output of the filter is achieved by simultaneously switching the switch control signals to alter the resonant frequencies of the series and parallel networks.

Preferably, the first, second, third, fourth, fifth, and sixth switches are all NMOS transistors. The first, third, and fifth transistor switches have a gate length of 60 nm and a gate width of 192 μm. The second, fourth, and sixth transistor switches have a gate length of 60 nm and a gate width of 64 μm. Their on-control voltage is 1 V, and their off-control voltage is 0 V.

Preferably, the first capacitor and the second capacitor are metal-oxide-metal capacitors, and the metal-oxide-metal capacitors employ an interdigitated structure.

Preferably, the capacitance value of the first capacitor is 115 fF, and the capacitance value of the second capacitor is 77 fF.

Preferably, the inductance value of the first inductor and the third inductor is 275 pH, and the inductance value of the second inductor is 150 pH.

The millimeter-wave low-pass/high-pass reconfigurable filter according to the disclosure firstly achieves the interchange of filter passband and stopband in two modes, and secondly achieves low passband loss and good image signal suppression in the stopband. By employing the low-pass/high-pass reconfigurable structure, it realizes output across multiple frequency bands in both low-frequency and high-frequency ranges.

Compared to the conventional technologies, the beneficial effects of the disclosure are as follows:
1. The millimeter-wave low-pass/high-pass reconfigurable filter of the disclosure can achieve reconfigurable filtering of millimeter-wave signals in different frequency bands. The implementation method enabling circuit structure reuse is highly suitable for multi-band millimeter-wave transceiver systems.
2. The millimeter-wave low-pass/high-pass reconfigurable filter of the disclosure can not only achieve the interchange of filter passband and stopband in two modes but also simultaneously achieve low loss in the passband and good signal suppression in the stopband. It is a reconfigurable filter circuit possessing an image signal suppression function. Conventional filter structures can only filter millimeter-wave signals in fixed frequency bands, limiting their application in multi-band communication systems.
3. The millimeter-wave low-pass/high-pass reconfigurable filter circuit of the disclosure has a simplified structure, is convenient for reconfiguration control, and has a low component count, making it easy to implement. It can effectively reduce cost and power consumption.

### BRIEF DESCRIPTION OF THE DRAWINGS

To provide a clearer explanation of the technical solutions in the embodiments of the disclosure or the prior art, the drawings required for describing the embodiments or the prior art will be briefly introduced below. It is apparent that the drawings in the following description are merely some embodiments of the disclosure. For those of ordinary skill in the art, other drawings may also be obtained from these drawings without creative efforts.

FIG. 1 is a structural diagram of the millimeter-wave low-pass/high-pass reconfigurable filter according to the disclosure;

FIG. 2 is a schematic circuit diagram of the first reconfigurable state in the disclosure;

FIG. 3 is a schematic circuit diagram of the second reconfigurable state in the disclosure;

FIG. 4 is a simulated transmission curve diagram of the millimeter-wave low-pass/high-pass reconfigurable filter according to the disclosure.

### DETAILED DESCRIPTION OF THE EMBODIMENTS

The technical solutions in the embodiments of the disclosure will be clearly and completely described below with reference to the accompanying drawings. It is apparent that the described embodiments are only a part of the embodiments of the disclosure, rather than all of them. Based on the embodiments of the disclosure, all other embodiments obtained by a person of ordinary skill in the art without creative efforts shall fall within the protection scope of the disclosure.

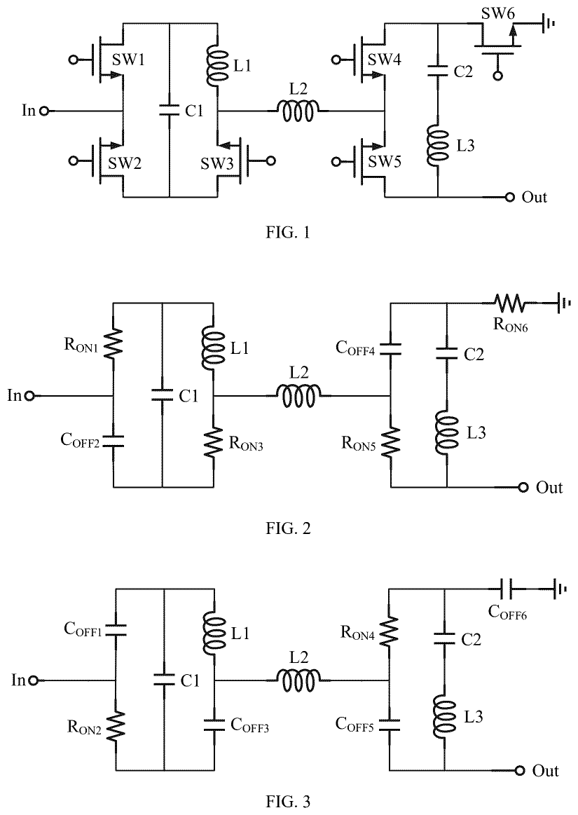

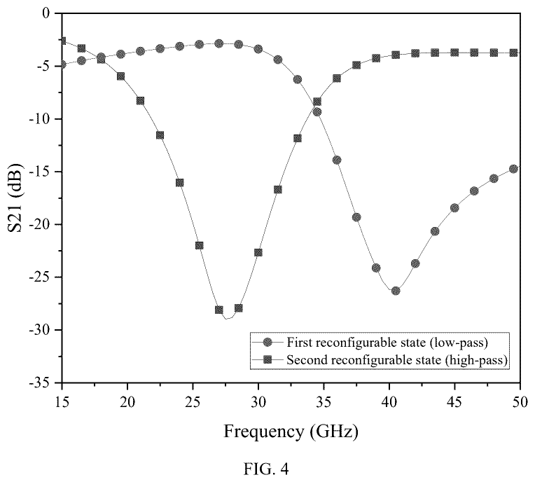

As shown in FIG. 1, a millimeter-wave low-pass/high-pass reconfigurable filter includes a series-parallel reconfiguration structure, a passband compensation inductor, and a ground-direct connection reconfiguration structure.

The series-parallel reconfiguration structure is a parallel resonant network including a first switch SW1, a second switch SW2, a third switch SW3, a first inductor L1 and first capacitor C1. The input terminal In is connected to one end of the first switch SW1 and one end of the second switch SW2. The other end of the first switch SW1 is connected to one end of the first capacitor C1 and one end of the first inductor L1. The other end of the second switch SW2 is connected to the other end of the first capacitor C1 and one end of the third switch SW3. The other end of the third switch SW3 is connected to the other end of the first inductor L1. The aforementioned components together constitute the series-parallel reconfiguration structure.

The passband compensation inductor includes a second inductor L2. One end of the second inductor L2 is connected to the other end of the third switch SW3 and the other end of the first inductor L1. The other end of the second inductor L2 is connected to one end of a fourth switch SW4 and one end of a fifth switch SW5. The passband compensation inductor is configured to resonate out the passband capacitance of the series-parallel reconfiguration structure.

The ground-direct connection reconfiguration structure is a series resonant network including a fourth switch SW4, a fifth switch SW5, a sixth switch SW6, and a third inductor L3 and second capacitor C2. The other end of the fourth switch SW4 is connected to one end of the second capacitor C2 and one end of the sixth switch SW6. The other end of the sixth switch SW6 is grounded. The other end of the fifth switch SW5 is connected to one end of the third inductor L3 and the output terminal Out. The other end of the third inductor L3 is connected to the other end of the second capacitor C2. The aforementioned components together constitute the ground-direct connection reconfiguration structure.

The first switch SW1, the third switch SW3, the fifth switch SW5, and the sixth switch SW6 are switched using the same control signal, meaning they are turned on and off simultaneously. The second switch SW2 and the fourth switch SW4 are switched using the same control signal, meaning they are turned on and off simultaneously.

In the millimeter-wave low-pass/high-pass reconfigurable filter, the first switch SW1, the second switch SW2, the third switch SW3, the fourth switch SW4, the fifth switch SW5, and the sixth switch SW6 are all NMOS transistor switches. Their gates serve as switch control terminals, and their sources and drains serve as the two terminals of the switch, respectively. When the first switch SW1, the third switch SW3, the fifth switch SW5, and the sixth switch SW6 are turned on, the NMOS transistor switches are equivalent to resistors R_{ON1,} R_{ON3,} R_{ON5,} R_{ON6}, respectively. When the second switch SW2 and the fourth switch SW4 are turned off, the NMOS transistor switches are equivalent to capacitors C_{OFF2} and C_{OFF4}, respectively. The millimeter-wave low-pass/high-pass reconfigurable filter structure operates in low-pass mode, as shown in FIG. 2. When the first switch SW1, the third switch SW3, the fifth switch SW5, and the sixth switch SW6 are turned off, the NMOS transistor switches are equivalent to capacitors C_{OFF1,} C_{OFF3,} C_{OFF5} and C_{OFF6}, respectively. When the second switch SW2 and the fourth switch SW4 are turned on, the NMOS transistor switches are equivalent to resistors R_{ON2} and R_{ON4}, respectively. The millimeter-wave low-pass/high-pass reconfigurable filter operates in high-pass mode, as shown in FIG. 3. By simultaneously switching the switch control signals, the interchange of filter passband and stopband in the two modes is achieved, thereby realizing reconfigurable frequency output of the filter.

The capacitor C1 and capacitor C2 are MOM (Metal-Oxide-Metal) capacitors. The MOM capacitors employ an interdigitated structure, which offers high quality factor and low loss.

The millimeter-wave low-pass/high-pass reconfigurable filter can achieve the interchange of filter passband and stopband in two modes through the turning on and off of the switches. It enables reconfigurable output in both high-frequency and low-frequency bands, features low loss in the passband and good image signal suppression in the stopband, and thereby achieves hardware reuse.

The disclosure is described below using an example of a millimeter-wave band low-pass/high-pass reconfigurable filter.

The millimeter-wave band low-pass/high-pass reconfigurable filter in the embodiment is designed using a 65 nm CMOS process. Among them, all six switches are constituted by NMOS transistors. The transistor switches SW1, SW3, and SW5 have a gate length of 60 nm and a gate width of 192 μm. The transistor switches SW2, SW4, and SW6 have a gate length of 60 nm and a gate width of 64 μm. Their on-control voltage is 1 V, and their off-control voltage is 0 V. The capacitance values of capacitor C1 and capacitor C2 are 115 fF and 77 fF, respectively. The inductance values of inductor L1, inductor L2, and inductor L3 are 275 pH, 150 pH, and 275 pH, respectively.

A circuit simulation tool was used to design and simulate this millimeter-wave low-pass/high-pass reconfigurable filter. When the four switches SW1, SW3, SW5, and SW6 are all turned on and the two switches SW2 and SW4 are both turned off, the first reconfigurable low-pass filter circuit is formed. It achieves a transmission loss of less than 3.4 dB in the 24˜30 GHz frequency band and a stopband signal suppression greater than 17.5 dB in the 37˜45.5 GHz frequency band. When the four switches SW1, SW3, SW5, and SW6 are all turned off and the two switches SW2 and SW4 are both turned on, the second reconfigurable high-pass filter circuit is formed. It achieves a transmission loss of less than 5.2 dB in the 37˜50 GHz frequency band and a stopband signal suppression greater than 16 dB in the 24˜31.5 GHz frequency band.

The implementation manners of the disclosure have been described in detail above with reference to the accompanying drawings. However, the disclosure is not limited to the described implementation manners. For those skilled in the art, various changes, modifications, substitutions, and variations can be made to these implementation manners without departing from the principle and spirit of the disclosure, and such changes shall still fall within the protection scope of the disclosure.

What is claimed is:

1. A millimeter-wave low-pass/high-pass reconfigurable filter comprising: a series-parallel reconfiguration structure, a passband compensation inductor, and a ground-direct connection reconfiguration structure;
wherein the series-parallel reconfiguration structure is a parallel resonant network comprising a first switch, a second switch, a third switch, a first inductor and a first capacitor; an input terminal is connected to one end of the first switch and one end of the second switch; the other end of the first switch is connected to one end of the first capacitor and one end of the first inductor; the other end of the second switch is connected to the other end of the first capacitor and one end of the third switch; the other end of the third switch is connected to the other end of the first inductor;
the passband compensation inductor includes a second inductor; one end of the second inductor is connected to the other end of the third switch and the other end of the first inductor; the other end of the second inductor is connected to one end of a fourth switch and one end of a fifth switch; the passband compensation inductor is configured to resonate out the passband capacitance of the series-parallel reconfiguration structure; and
the ground-direct connection reconfiguration structure is a series resonant network comprising a fourth switch, a fifth switch, a sixth switch, a third inductor and a second capacitor; the other end of the fourth switch is connected to one end of the second capacitor and one end of the sixth switch; the other end of the sixth switch is grounded; the other end of the fifth switch is connected to one end of the third inductor and an output terminal; the other end of the third inductor is connected to the other end of the second capacitor.

2. The millimeter-wave low-pass/high-pass reconfigurable filter of claim 1, wherein the first switch, the third switch, the fifth switch, and the sixth switch are configured to be switched using the same control signal to achieve simultaneous turning-on and turning-off; and the second switch and the fourth switch are configured to be switched using the same control signal to achieve simultaneous turning-on and turning-off.

3. The millimeter-wave low-pass/high-pass reconfigurable filter of claim 2, wherein the first switch, the second switch, the third switch, the fourth switch, the fifth switch, and the sixth switch are all NMOS transistor switches, wherein a gate thereof is a switch control terminal, and a source and a drain thereof are two terminals of the switch respectively; when the first, second, third, fourth, fifth, and sixth switches are turned on, the NMOS transistor switches are equivalent to resistors, and when turned off, the NMOS transistor switches are equivalent to capacitors; reconfigurable frequency output of the filter is achieved by simultaneously switching the switch control signals to change the resonant frequencies of the series and parallel networks.

4. The millimeter-wave low-pass/high-pass reconfigurable filter of claim 3, wherein the first, second, third, fourth, fifth, and sixth switches are composed of NMOS transistors; the first, third, and fifth transistor switches have a gate length of 60 nm and a gate width of 192 μm; the second, fourth, and sixth transistor switches have a gate length of 60 nm and a gate width of 64 μm; an on-control voltage thereof is 1V, and an off-control voltage thereof is 0V.

5. The millimeter-wave low-pass/high-pass reconfigurable filter of claim 1, wherein the first capacitor and the second capacitor are metal-oxide-metal capacitors, and the metal-oxide-metal capacitors employ an interdigitated structure.

6. The millimeter-wave low-pass/high-pass reconfigurable filter of claim 5, wherein the capacitance value of the first capacitor is 115 fF, and the capacitance value of the second capacitor is 77 fF.

7. The millimeter-wave low-pass/high-pass reconfigurable filter of claim 1, wherein the inductance value of the first inductor and the third inductor is 275 pH, and the inductance value of the second inductor is 150 pH.
